(19) United States
(12) Patent Application Publication
(10) Pub. No.: US 2012/0097227 A1
(43) Pub. Date: Apr. 26, 2012

(54) SOLAR CELLS

(75) Inventors: JungWook LIM, Daejeon (KR); Seong Hyun Lee, Busan (KR); Sun Jin Yun, Daejeon (KR)

(73) Assignee: ELECTRONICS AND TELECOMMUNICATIONS RESEARCH INSTITUTE, Daejeon (KR)

(21) Appl. No.: 13/182,850

(22) Filed: Jul. 14, 2011

(30) Foreign Application Priority Data
Oct. 22, 2010 (KR) 10-2010-0103366

(51) Int. Cl. H01L 31/075

(52) U.S. Cl. 136/255

(57) ABSTRACT

Provided is a solar cell. The solar cell includes: a light absorbing layer; a window layer consisting of a p-type copper oxynitride layer on the light absorbing layer; a rear electrode below the light absorbing layer; and a transparent electrode on the window layer.

### CROSS-REFERENCE TO RELATED APPLICATIONS

This U.S. non-provisional patent application claims priority under 35 U.S.C. §119 of Korean Patent Application No. 10-2010-0103366, filed on Oct. 22, 2010, the entire contents of which are hereby incorporated by reference.

### BACKGROUND OF THE INVENTION

The present invention disclosed herein relates to optical devices, and more particularly, to solar cells.

A solar cell (or a photovoltaic cell) is a device that directly converts solar light into electricity. In the solar cell, electron-hole pairs are generated, into which solar light having a higher energy than a band gap energy of a semiconductor is incident. The electron-hole pairs are transferred by an electric field formed in a semiconductor p-n junction, thereby generating electromotive force.

As a material of the solar cell, a copper oxide layer has a relatively simple composition and consists of abundant elements on earth. Accordingly, if the cooper oxide layer is used as a component of the solar cell, low manufacturing cost may be achieved.

### SUMMARY OF THE INVENTION

The present invention provides solar cells using a copper oxynitride layer.

Embodiments of the present invention provide solar cells including: a light absorbing layer; a window layer consisting of a p-type copper oxynitride layer on the light absorbing layer; a rear electrode below the light absorbing layer; and a transparent electrode on the window layer.

In some embodiments, the p-type copper oxynitride layer Cu₂OₓN_{y} may satisfy the conditions of x+y=1 and y is greater than 0 and less than 0.01.

In other embodiments, a band gap energy of the window layer may be greater than that of the light absorbing layer, and the window layer may transmit solar light incident from the transparent electrode.

In still other embodiments, the light absorbing layer may include one of amorphous silicon, amorphous silicon germanium, micro-crystalline silicon, micro-crystalline silicon germanium, crystalline silicon, crystalline silicon germanium, copper oxide, zinc oxide, or titanium oxide.

In even other embodiments, the solar cells may further include an n-type layer between the light absorbing layer and the rear electrode, wherein the window layer, the n-type layer, and the light absorbing layer constitute a p-i-n structure.

In yet other embodiments, the window layer and the light absorbing layer may constitute a p-n structure.

In further embodiments, the solar cells may further include an optional window layer between the light absorbing layer and the window layer.

In still further embodiments, a band gap energy of the optional window layer may be less than that of the window layer.

In even further embodiments, a refractive index of the window layer is greater than that of the transparent electrode and less than that of the light absorbing layer.

In yet further embodiments, the solar cells may further include an upper light absorbing layer between the window layer and the transparent electrode, wherein the window layer transmits a portion of solar light incident from the transparent electrode and reflects other portions.

In yet further embodiments, light absorbed by the light absorbing layer may have a shorter wavelength than that absorbed by the upper light absorbing layer.

In yet further embodiments, each of the light absorbing layer and the upper light absorbing layer may have a p-i-n structure.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a sectional view illustrating a solar cell according to a first embodiment of the present invention;

FIG. 2 is a sectional view illustrating a solar cell according to a second embodiment of the present invention;

FIG. 3 is a sectional view illustrating a solar cell according to a third embodiment of the present invention;

FIG. 4 is a sectional view illustrating a solar cell according to a fourth embodiment of the present invention;

FIG. 5 is a sectional view illustrating a solar cell according to a fifth embodiment of the present invention; and

FIG. 6 is a graph illustrating transmittance according to a wavelength toward a copper oxynitride layer according to embodiments of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the present invention. An embodiment described and exemplified herein includes a complementary embodiment thereof.

The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

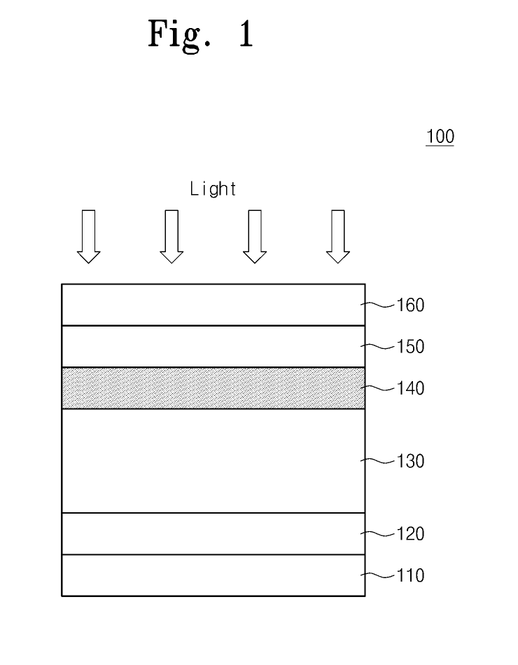

FIG. 1 is a sectional view illustrating a solar cell according to a first embodiment of the present invention.

Referring to FIG. 1, the solar cell 100 according to the first embodiment of the present invention includes a light absorbing layer 130, a window layer 140 consisting of a p-type copper oxynitride layer on the light absorbing layer 130, a rear electrode 110 below the light absorbing layer 130, and a transparent electrode 150 on the window layer 140.

An n-type layer 120 is interposed between the light absorbing layer 130 and the rear electrode 110, and the window layer 140, the light absorbing layer 130, and the n-type layer 120 may constitute a p-i-n structure. A glass substrate 160 may be disposed on the transparent electrode 150. An external solar light may be incident through the glass substrate 160. This structure may be called a superstrate structure. Unlike this, when the transparent electrode 150 and the glass substrate 160 are disposed below, the solar light may be incident into the solar cell 100 in the opposite direction. This structure may be called a substrate structure.

The window layer 140 may consist of a p-type copper oxynitride layer Cu₂OₓN_{y}. In the p-type copper oxynitride layer Cu₂OₓN_{y}, it satisfies the condition of x+y=1 and y may be greater than 0 and less than 0.01. The cooper oxynitride layer of the window layer 140 may contain a very small amount of nitrogen. The cooper oxynitride layer of the window layer 140 needs to have a sufficiently high band gap energy to increase transmittance about light. A band gap energy of Cu₂O may be about 2.1 eV; a band gap energy of CuO may be about 2.5 eV; a band gap energy of the cooper oxynitride layer according to the first embodiment may be about 2.5 eV. Since the cooper oxynitride layer of the window layer 140 allows a copper oxide layer to contain nitrogen, it may have a higher band gap energy than that of the copper oxide layer. The copper oxide layer is known as a p-type semiconductor material without adding a special doping material.

The cooper oxynitride layer used for the window layer 140 may be formed by injecting oxygen and nitrogen simultaneously with adjustment of a deposition temperature and a plasma power. Nitrogen may be provided by ammonia or nitrogen dioxide. In more detail, the copper oxynitride layer may be formed through a sputtering method. When the sputtering method is used, argon, oxygen, and nitrogen gases are provided using copper as a target or argon, oxygen, and nitrogen gases are provided using a copper oxide as a target. Additionally, the copper oxynitride layer may be formed though various methods such as a chemical vapor deposition method, an atomic layer deposition method, an evaporation method, or a sol-gel method.

Since the window layer 140 is disposed between the transparent electrode 150 and the light absorbing layer 130, its resistivity needs to be sufficiently low. The window layer 140 may have a thickness of less than about 50 nm and its resistivity may be less than about 10³ Ω·cm. Under this condition, in relation to the copper oxynitride layer used for the window layer 140, transmittance of light having a wavelength of about 500 nm to about 1000 nm may be more than 80%.

The transparent electrode 150 may be one of a zinc oxide (ZnO) layer doped with aluminum (Al), a zinc oxide (ZnO) layer doped with gallium (Ga), an indium tin oxide (ITO) layer, a tin oxide (SnO₂) layer, a ruthenium oxide (RuO₂) layer, an iridium oxide (IrO₂) layer, and a copper oxide (Cu₂O) layer. More specifically, the light absorbing layer 130 may include one of amorphous silicon, amorphous silicon germanium, micro-crystalline silicon, micro-crystalline silicon germanium, crystalline silicon, or crystalline silicon germanium. Or, the light absorbing layer 130 may be a copper oxide layer of Cu₂O, CuO or a combination thereof. The light absorbing layer 130 may include one of zinc oxide (ZnO) or titanium oxide (TiO2).

If the light absorbing layer 130 and the n-type layer 120 are amorphous silicon, the solar light transmitting the window layer 140 is absorbed in the amorphous silicon. This is because a band gap energy of the amorphous silicon is between about 1.7 eV to about 2.0 eV and the copper oxynitride layer used as the window layer 140 has a band gap energy of more than about 2.5 eV. In this case, a solar light in a wavelength band of about 450 nm to about 550 nm effectively transmits the window layer 140 to be absorbed in the light absorbing layer 130.

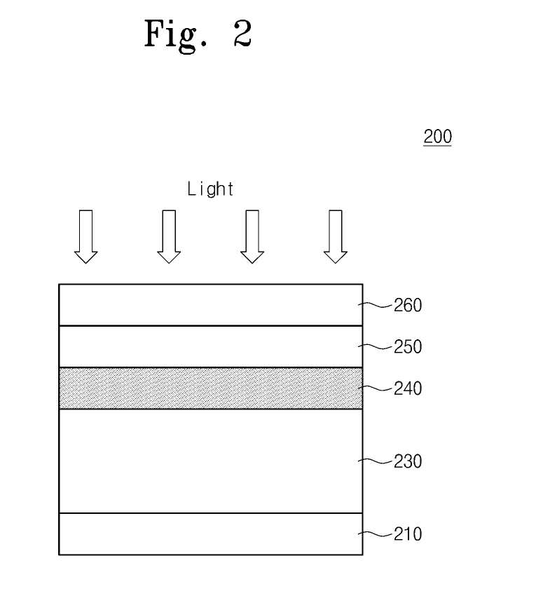

FIG. 2 is a sectional view illustrating a solar cell according to a second embodiment of the present invention. The technical features described in the first embodiment of FIG. 1 will be omitted for conciseness.

Referring to FIG. 2, the solar cell 200 according to the second embodiment of the present invention includes a light absorbing layer 230, a window layer 240 consisting of a p-type copper oxynitride layer on the light absorbing layer 230, a rear electrode 210 below the light absorbing layer 230, and a transparent electrode 250 on the window layer 240.

The light absorbing layer 230 may be an n-type semiconductor. The window layer 240 and the light absorbing layer 230 may constitute a p-n structure. A glass substrate 260 may be disposed on the transparent electrode 250. An external solar light may be incident through the glass substrate 260. This structure may be called a superstrate structure. Unlike this, when the transparent electrode 250 and the glass substrate 260 are disposed below, the solar light may be incident into the solar cell 200 in the opposite direction. This structure is called a substrate structure.

The window layer 240 may consist of a p-type copper oxynitride layer Cu₂OₓN_{y}. In the p-type copper oxynitride layer Cu₂OₓN_{y}, it satisfies the condition of x+y=1 and y may be greater than 0 and less than 0.01. The cooper oxynitride layer of the window layer 240 may contain a very small amount of nitrogen.

The window layer 240 has a higher band gap energy than that of the light absorbing layer 230. The window layer 240 transmits the solar light and the light absorbing layer 230 may serve to absorb the solar light.

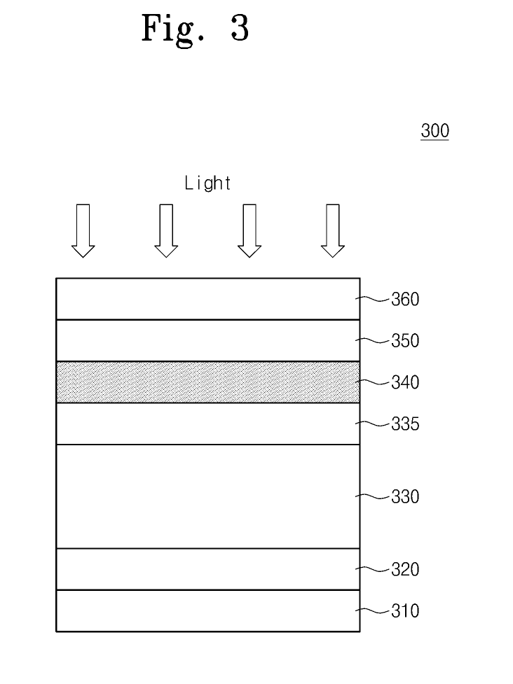

FIG. 3 is a sectional view illustrating a solar cell according to a third embodiment of the present invention. The technical features described in the first embodiment of FIG. 1 will be omitted for conciseness.

Referring to FIG. 3, the solar cell 300 according to the third embodiment of the present invention includes a light absorbing layer 330, a window layer 340 consisting of a p-type copper oxynitride layer on the light absorbing layer 330, a rear electrode 310 below the light absorbing layer 330, and a transparent electrode 350 on the window layer 340.

An optional window layer 335 may be interposed between the light absorbing layer 330 and the window layer 340. The optional window layer 335 has a smaller band gap energy than that of the window layer 340. The optional window layer 335 may be CuO, Cu₂O or Cu₂OₓN_{y}. Or, the optional window layer 335 may include one of amorphous silicon, amorphous silicon germanium, micro-crystalline silicon, micro-crystalline silicon germanium, crystalline silicon, crystalline silicon germanium, or zinc oxide.

The optional window layer 335 changes a band gap energy to improve an open-circuit voltage (Voc) value and a fill factor value of the solar cell 300. The optional window layer 335 may serve as a buffer layer between the window layer 340 and the light absorbing layer 330. That is, the optional window layer 335 may alleviate crystalline limitation or interface mismatch (e.g., lattice constant difference) between the window layer 340 and the light absorbing layer 330. Moreover, the optional window layer 335 has a higher refractive index than that of the window layer 340 and a lower refractive index than that of the light absorbing layer 330, so that it may serve as an anti-reflection layer. Or, the optional window layer 335 prevents electron-hole recombination so that electrons may be transferred without difficulty or internal electric field may be improved.

An n-type layer 320 may be interposed between the light absorbing layer 330 and the rear electrode 310. The light absorbing layer 330 may be an intrinsic layer. The window layer 340, the optional window layer 335, the light absorbing layer 330, and the n-type layer 320 may constitute a p-i-n structure.

A glass substrate 360 may be disposed on the transparent electrode 350. An external solar light may be incident through the glass substrate 360. This structure may be called a superstrate structure. Unlike this, when the transparent electrode 350 and the glass substrate 360 are disposed below, the solar light may be incident into the solar cell 300 in the opposite direction. This structure is called a substrate structure.

The window layer 340 may consist of a p-type copper oxynitride layer Cu₂OₓN_{y}. In the p-type copper oxynitride layer Cu₂OₓN_{y}, it satisfies the condition of x+y=1 and y may be greater than 0 and less than 0.01. The cooper oxynitride layer of the window layer 340 may contain a very small amount of nitrogen.

The window layer 340 has a higher band gap energy than that of the light absorbing layer 330. The window layer 340 transmits the solar light and the light absorbing layer 330 may serve to absorb the solar light.

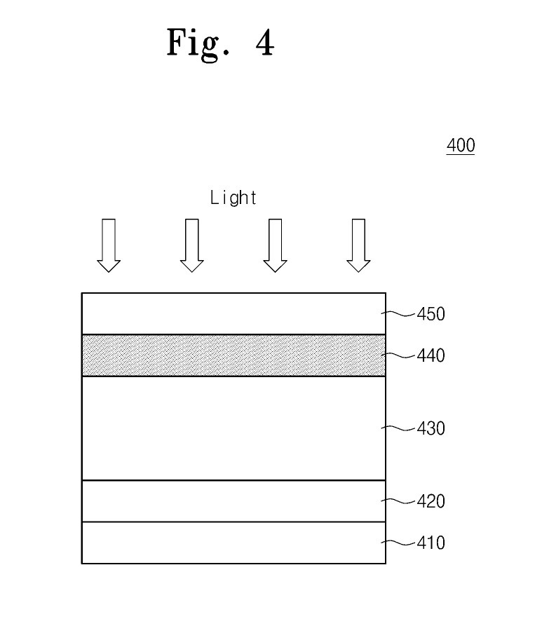

FIG. 4 is a sectional view illustrating a solar cell according to a fourth embodiment of the present invention. The technical features described in the first embodiment of FIG. 1 will be omitted for conciseness.

Referring to FIG. 4, the solar cell 400 according to the fourth embodiment of the present invention includes a light absorbing layer 430, a window layer 440 consisting of a p-type copper oxynitride layer on the light absorbing layer 430, a rear electrode 410 below the light absorbing layer 430, and a transparent electrode 450 on the window layer 440.

The window layer 440 has a higher refractive index than that of the transparent electrode 450 and a lower refractive index than that of the light absorbing layer 430. The window layer 440 may prevent the reflection of an incident solar light. A refractive index of the window layer 440 may be adjusted between about 1.8 to about 3.0 to satisfy the above condition.

The window layer 440 may consist of a p-type copper oxynitride layer Cu₂OₓN_{y}. In the p-type copper oxynitride layer Cu₂OₓN_{y}, it satisfies the condition of x+y=1 and y may be greater than 0 and less than 0.01. The cooper oxynitride layer of the window layer 440 may contain a very small amount of nitrogen.

The window layer 440 has a higher band gap energy than that of the light absorbing layer 430. The window layer 440 transmits a solar light and the light absorbing layer 430 may serve to absorb the solar light. Accordingly, the window layer 440 may transmit solar light into the light absorbing layer 430 with a high band gap energy and a proper refractive index value.

The light absorbing layer 430 may be an intrinsic layer. An n-type layer 430 may be interposed between the light absorbing layer 430 and the rear electrode 410. The window layer 440, the light absorbing layer 430, and the n-type layer 420 may constitute a p-i-n structure. A glass substrate 460 may be disposed on the transparent electrode 450.

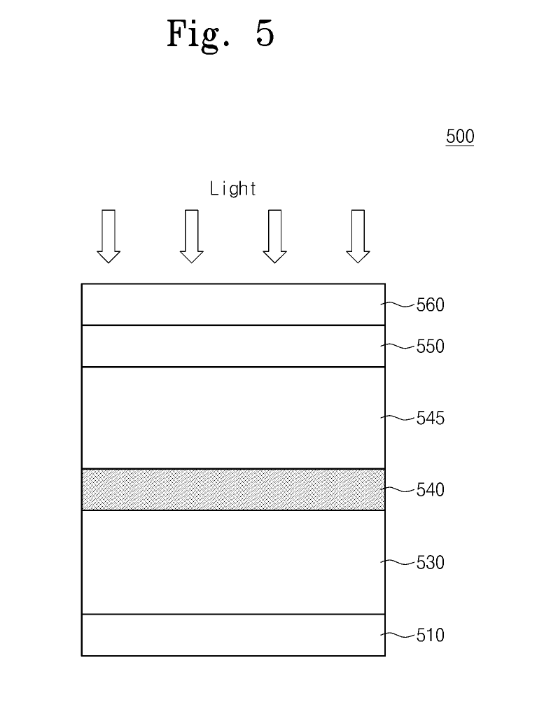

FIG. 5 is a sectional view illustrating a solar cell according to a fifth embodiment of the present invention. The technical features described in the first embodiment of FIG. 1 will be omitted for conciseness.

Referring to FIG. 5, the solar cell 500 according to the fifth embodiment of the present invention includes a light absorbing layer 530, a window layer 540 consisting of a p-type copper oxynitride layer on the light absorbing layer 530, a rear electrode 510 below the light absorbing layer 530, a transparent electrode 550 on the window layer 540, and an upper light absorbing layer 545 interposed between the window layer 540 and the transparent electrode 550. A glass substrate 560 may be disposed on the transparent electrode 550.

The window layer 540 transmits a portion of a solar light incident from the transparent electrode 550 and reflects other portions. A light absorbed by the light absorbing layer 530 may has a shorter wavelength than that absorbed by the upper light absorbing layer 545. That is, the window layer 540 selectively transmits a light of a specific wavelength band and reflects a light of a specific wavelength band. The solar cell 500 having the above structure is called a tandem type solar cell.

For example, the upper light absorbing layer 545 may include amorphous silicon and the light absorbing layer 530 may include micro-crystalline silicon or amorphous silicon germanium. A band gap energy of amorphous silicon is greater than that of micro-crystalline silicon or amorphous silicon germanium. The window layer 540 reflects the solar light of a short wavelength absorbed in the upper light absorbing layer 545 and transmits the solar light of a long wavelength absorbed in the light absorbing layer 530.

Each of the light absorbing layer 530 and the upper light absorbing layer 545 may have a p-i-n structure. The window layer 540 may consist of a p-type copper oxynitride layer Cu₂OₓN_{y}. In the p-type copper oxynitride layer Cu₂OₓN_{y}, it satisfies the condition of x+y=1 and y may be greater than 0 and less than 0.01. The cooper oxynitride layer of the window layer 540 may contain a very small amount of nitrogen. The copper oxynitride layer may have a band gap energy of more than about 2.5 eV, a thickness of about 1 nm to about 300 nm, and a resistivity of less than about 10⁴ Ω·cm.

Unlike this, the window layer 540 and the light absorbing layer 530 may constitute a p-n structure. The copper oxynitride layer may have a band gap energy of more than about 2.5 eV, a thickness of about 1 nm to about 50 nm, and a resistivity of less than about 10³ Ω·cm.

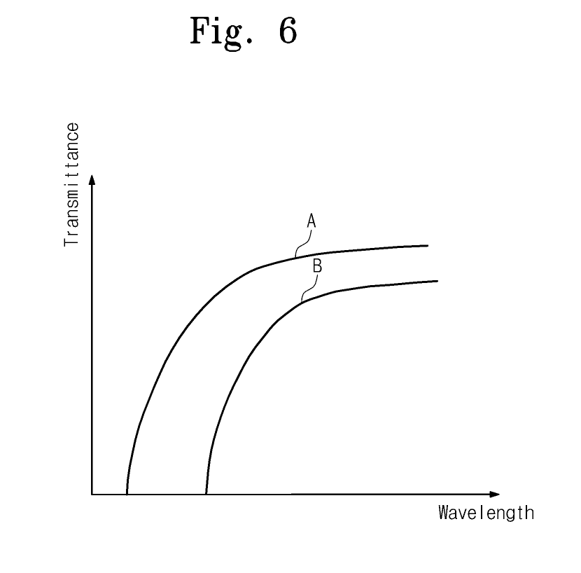

FIG. 6 is a graph illustrating transmittance according to a wavelength toward a copper oxynitride layer according to embodiments of the present invention.

Referring to FIG. 6, A represents a copper oxynitride layer according to embodiments of the present invention and B represents a typical copper oxide layer. The copper oxynitride layer has a band gap energy of more than about 2.5 eV and the copper oxide layer has a band gap energy of about 2.5 eV (i.e., 1.5 eV to 2.5 eV). As shown in the graph, case A shows more excellent transmittance than that of case B. As a thickness of thin film corresponding to cases A and B becomes thinner, the curves move to the left entirely and this means that a wavelength range that a light transmits may broaden. Although resistivity is drastically increased as a thickness of the thin film is thinner less than about 30 nm in the case B, even when the thin film corresponding to the case A becomes thinner less than about 30 nm, it is observed that resistivity of less than 10³ Ω·cm is maintained.

According to embodiments of the present invention, a solar cell includes a window layer consisting of a copper oxynitride layer. Since the copper oxynitride layer has a band gap energy of more than about 2.5 eV, a property transmitting incident a solar light is excellent. Accordingly, manufacturing cost for the solar cell with the copper oxynitride layer may be reduced.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell comprising:
a light absorbing layer;
a window layer consisting of a p-type copper oxynitride layer on the light absorbing layer;
a rear electrode below the light absorbing layer; and
a transparent electrode on the window layer.

2. The solar cell of claim 1, wherein the p-type copper oxynitride layer Cu₂OₓN_{y} satisfies the conditions of x+y=1 and y is greater than 0 and less than 0.01.

3. The solar cell of claim 1, wherein a band gap energy of the window layer is greater than that of the light absorbing layer, and
wherein the window layer transmits solar light incident from the transparent electrode.

4. The solar cell of claim 1, wherein the light absorbing layer comprises one of amorphous silicon, amorphous silicon germanium, micro-crystalline silicon, micro-crystalline silicon germanium, crystalline silicon, crystalline silicon germanium, copper oxide, zinc oxide, or titanium oxide.

5. The solar cell of claim 1, further comprising an n-type layer between the light absorbing layer and the rear electrode,
wherein the window layer, the n-type layer, and the light absorbing layer constitute a p-i-n structure.

6. The solar cell of claim 1, wherein the window layer and the light absorbing layer constitute a p-n structure.

7. The solar cell of claim 1, further comprising an optional window layer between the light absorbing layer and the window layer.

8. The solar cell of claim 7, wherein a band gap energy of the optional window layer is less than that of the window layer.

9. The solar cell of claim 1, wherein a refractive index of the window layer is greater than that of the transparent electrode and less than that of the light absorbing layer.

10. The solar cell of claim 1, further comprising an upper light absorbing layer between the window layer and the transparent electrode,
wherein the window layer transmits a portion of solar light incident from the transparent electrode and reflects other portions.

11. The solar cell of claim 10, wherein light absorbed by the light absorbing layer has a shorter wavelength than that absorbed by the upper light absorbing layer.

12. The solar cell of claim 10, wherein each of the light absorbing layer and the upper light absorbing layer has a p-i-n structure.
